(19) United States
(12) Patent Application Publication
(10) Pub. No.: US 2025/0379086 A1
(43) Pub. Date: Dec. 11, 2025

(54) MONITORING SYSTEM, MARK DETECTION APPARATUS AND MONITORING METHOD FOR HEALTHY OF ELECTROSTATIC CHUCK

(71) Applicant: Taiwan Semiconductor Manufacturing Company, Ltd., Hsinchu (TW)

(72) Inventors: Yen-Chen CHEN, Hsinchu (TW); Chia-Hsien CHEN, Hsinchu (TW); Ling-Sung WANG, Hsinchu (TW); Chao-Lin LO, Hsinchu (TW); Chung-Tsung LU, Hsinchu (TW); Chia-Chin TSAI, Hsinchu (TW)

(73) Assignee: Taiwan Semiconductor Manufacturing Company, Ltd., Hsinchu (TW)

(21) Appl. No.: 18/736,053

(22) Filed: Jun. 6, 2024

(51) Int. Cl. H01L 21/683; H01L 21/67; H01L 21/687

(52) U.S. Cl. CPC H01L 21/6833; H01L 21/67242; H01L 21/6875

(57) ABSTRACT

A monitoring system includes an electrostatic chuck apparatus and a mark detection apparatus. The electrostatic chuck apparatus includes a base and an electrostatic chuck. The electrostatic chuck is disposed on the base, includes a plurality of supporting posts, and is configured to hold a wafer with the supporting posts. The mark detection apparatus includes an image capturing device and a mark analysis device. The image capturing device is configured to capture a wafer image of the wafer, wherein the wafer image includes a plurality of marks, and at least one of the marks is corresponding to at least one of the supporting posts. The mark analysis device is electrically connected with the image capturing device and configured to obtain a total mark-ratio of the number of the marks to the number of the supporting posts.

### BACKGROUND

An electrostatic chuck (ESC) may hold the wafer and heats the wafer for semiconductor manufacturing process. However, unhealthy ESC has abnormal dimple height that caused the wafer high warpage induce wafer crack and broken.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a function block of a monitoring system according to an embodiment of the present disclosure;

FIG. 1B illustrates a schematic diagram of an electrostatic chuck apparatus in FIG. 1A;

FIG. 1C illustrates a schematic diagram of a mark detection apparatus in FIG. 1A;

FIG. 2A illustrates a schematic diagram of the wafer image in FIG. 1C;

FIG. 2B illustrates a schematic diagram of the marks (or called “target mark”) in FIG. 1A being remained and the marks (or called “non-target mark”) in FIG. 1A being deleted;

FIG. 2C illustrates a schematic diagram of an engineer drawing 30 according to an embodiment of the disclosure;

FIG. 3 illustrates a schematic diagram of a relationship between the time and the total mark-ratio R1t according to an embodiment of the present disclosure; and

FIG. 4 illustrates a schematic diagram of a flow chart of a monitoring method of the monitoring system in FIG. 1A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

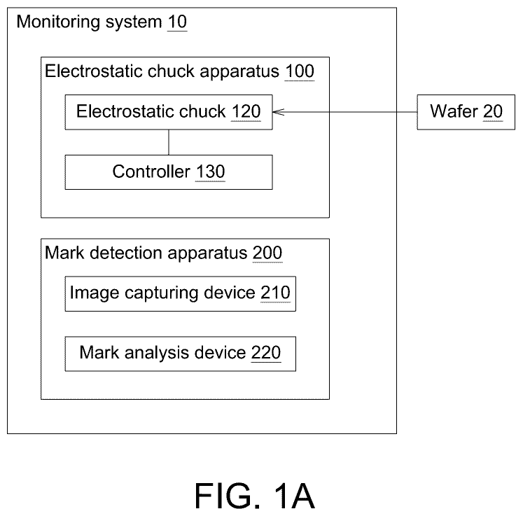

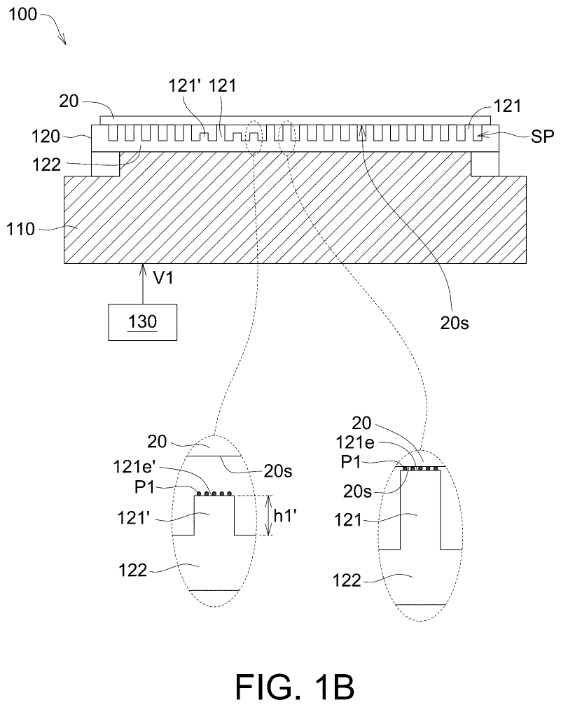

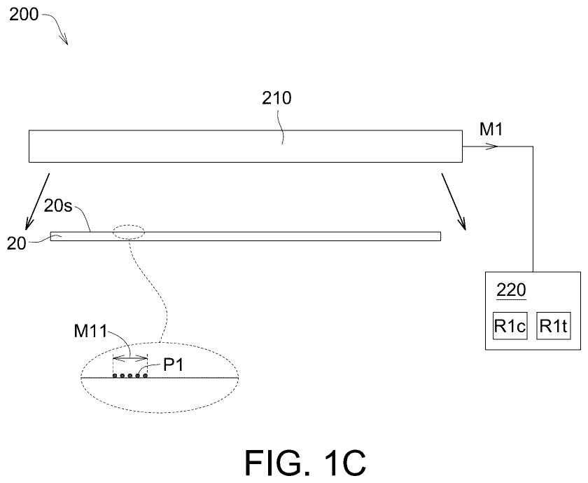

Referring to FIGS. 1A to 1C, FIG. 1A illustrates a schematic diagram of a function block of a monitoring system 10 according to an embodiment of the present disclosure, FIG. 1B illustrates a schematic diagram of an electrostatic chuck apparatus 100 in FIG. 1A, and FIG. 1C illustrates a schematic diagram of a mark detection apparatus 200 in FIG. 1A.

As illustrated in FIG. 1A, the monitoring system 10 includes an electrostatic chuck apparatus 100 and a mark detection apparatus 200. The electrostatic chuck apparatus 100 includes a base 110 (the base 110 is shown in FIG. 1B), an electrostatic chuck (ESC) 120 and a controller 130. The mark detection apparatus 200 includes an image capturing device 210 and the mark analysis device 220. As illustrated in FIG. 1B, the electrostatic chuck 120 is disposed on the base 110 and includes a plurality of supporting posts (or called “supporting component” or “dimple”) 121. The electrostatic chuck 120 is configured to hold a wafer 20 with the supporting posts 121. As illustrated in FIG. 1C, the image capturing device 210 is configured to capture a wafer image M1 of the wafer, wherein the wafer image M1 includes a plurality of marks M11 corresponding to at least one of the supporting posts 121. The mark analysis device 220 is electrically connected with the image capturing device 210 and configured to obtain a total mark-ratio R1t of the marks M11 to the supporting posts 121. In an embodiment, the total mark-ratio R1t may be used to determine a health level of the electrostatic chuck 120.

As illustrated in FIG. 1B, the supporting post 121 has a terminal surface 121e on which a plurality of particles P1 is formed. When the wafer 20 is contact with the terminal surface 121e of the electrostatic chuck 120, the particles adhere to a marked surface 20s of the wafer 20. In an embodiment, the wafer 20 is a blank wafer without any circuit structure, deposition semiconductor film, etc. In an embodiment, the marked surface 20s may be a front side of a back side of the wafer 20.

As illustrated in FIG. 1B, the base 110 may be formed of a conductive material, for example, metal (such as aluminum). The electrostatic chuck 120 further includes a plate 122 to which the supporting posts 121 are connected. In an embodiment, the plate 122 and the supporting posts 121 are integrated into one piece. The electrostatic chuck 120 may be formed of a ceramic material. The supporting posts 121 are protruded relative to an upper surface of the plate 122. The controller 130 may control a power source to apply a high voltage V1 to the base 110. The electrostatic chuck 120 may generate an electrostatic attraction due to the high voltage V1 to hold the wafer 20 with the supporting posts 121.

As shown in Table 1 below, the high voltage V1 (may be equal to or greater than 3600 psi) may be applied to the base 110 for a period ranging between 30 seconds to 60 seconds for stably holding the wafer 20. In addition, the gas (for example, helium) may be applied to space SP between the wafer 20 and the electrostatic chuck 120 for balance the chucking of the electrostatic chuck 120 to avoid the damage resulted from the chucking. In an embodiment, the gas pressure may be, for example, 20 torr, even less or greater. When de-chucking, the controller 130 does not apply the high voltage V1 to the base 110 for at least 8 seconds.

TABLE 1

| | MN-BSPA Recipe Setting | |
|---|---|---|
| | Chucking operation | De-chunk operation |
| Bias RF control mode | Voltage | voltage |
| Process time (second) | 30 to 60 | 8 |
| Helium (torr) | 20 | 0 |
| ESC holding voltage | 3600 | 0 |
| (Volt) | | |

In an embodiment, not all supporting posts 121 is in contact with the wafer 20. Furthermore, at least one supporting post 121′ is shorten due to wear and thus can't be in contact with the wafer 20. In such situation, the particles P1 on a terminal surface 121e′ of the supporting post 121′ can't adhere to the wafer 20, and thus the mark M11 can't be formed on the wafer 20. In an embodiment, the brand new (or unused) supporting post has an original height ranging between, for example, 8 micrometers and 12 micrometers. The height h1′ of the supporting post 121 is shorten with usage time of the electrostatic chuck 120, and thus the height h1′ of the supporting post 121′ can't be in contact with the wafer 20.

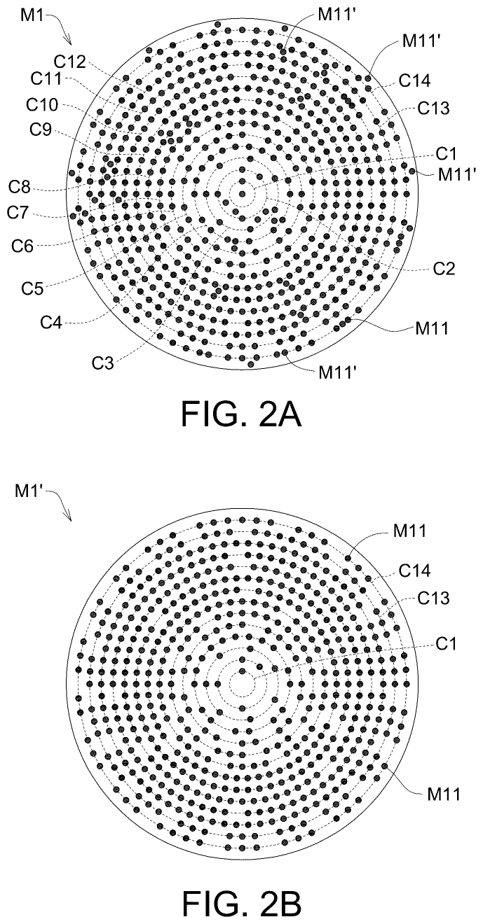

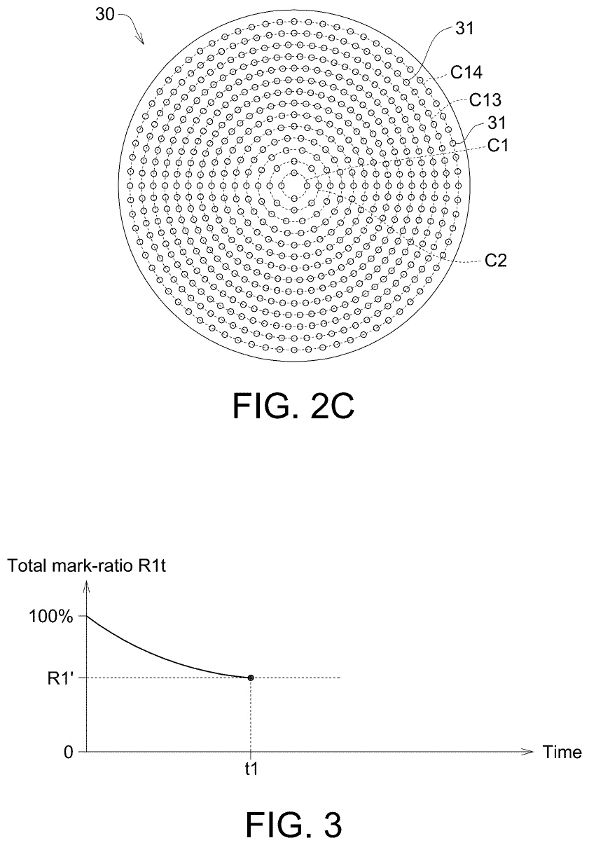

Referring to FIGS. 2A to 2C, FIG. 2A illustrates a schematic diagram of the wafer image M1 in FIG. 1C, FIG. 2B illustrates a schematic diagram of the marks M11 (or called “target mark”) in FIG. 1A being remained and the marks M11′ (or called “non-target mark”) in FIG. 1A being deleted, and FIG. 2C illustrates a schematic diagram of an engineer drawing 30 according to an embodiment of the disclosure.

As illustrated in FIG. 2A, not all marks in the wafer image M1 is formed by the supporting post 121. For example, the formation of the mark M11′ is not created by the supporting post 121 while the formation of the mark M11 is created by the supporting post 121.

As illustrated in FIG. 2A, the marks M11 which are formed by the supporting posts 121 are arranged in a plurality of circles C1, each circle C1 has different inner diameter. At least one mark M11′ which are not formed by the supporting posts 121 may be formed on (overlaps) at least one the circles C1 or formed between two circles C1 (not overlap) in the wafer image M1. The mark analysis device 220 may delete all marks M11′ which are not formed by the supporting posts 121 in the wafer image M1, as illustrated in FIG. 2B.

Furthermore, as illustrated in FIG. 2A, the mark analysis device 220 is further configured to determine whether a compared one (or each) of the marks is corresponding to any one of the supporting posts 121 in position by an image analysis technology; and if there is no supporting post 121 corresponding to the compared one, delete the compared one in the wafer image M11. For example, the mark M11′ appearing in the wafer image M1 is not corresponding to any supporting post symbol 31 in the engineer drawing 30, and accordingly the mark analysis device 220 deletes the mark M11′ in the wafer image M1 as illustrated in FIG. 2B. As illustrated in FIG. 2C, all supporting post symbols 31 are corresponding to all supporting posts 121 of the electrostatic chuck 120 of FIG. 1B in position, and the number of the supporting post symbols 31 in the engineer drawing 30 and the number of the supporting posts 121 of the electrostatic chuck 120 are equal.

In an embodiment, the mark analysis device 220 is further configured to obtain the number of the marks M11 of the wafer image M1 in FIG. 2B by the image analysis technology, obtain the number of the supporting posts 121 according to the engineer drawing 30, and obtain the total mark-ratio R1t of the number of the marks M11 to the number of the supporting posts 121.

In an embodiment, as shown in Table 2 below, the mark analysis device 220 is further configured to obtain the number of the marks M11 in each circle in the wafer image M1 in FIG. 2B by using the image analysis technology; obtain a mark sum of the number of the marks M11 for all circles C1 to C14 in the wafer image M1 in FIG. 2B by using the image analysis technology; obtain the number of the supporting post symbols 31 in each circle in the engineer drawing 30 in FIG. 2C, obtain a symbol sum of the number of the supporting post symbols 31 for all circles C1 to C14 in the engineer drawing 30 in FIG. 2C, and obtain the total mark-ratio R1t of the to the symbol sum. In addition, the number of the supporting post symbols 31 for each circle and/or the symbol sum of the number of the supporting post symbols 31 for all circles C1 to C14 in Table 2 may be pre-stored in the mark analysis device 220.

TABLE 2

| | | | the number of the | |
|---|---|---|---|---|
| | inner | the number of | supporting post | circle |
| | diameter | the marks M11 | symbols 31 for | mark-ratio |
| circle | (mm) | for each circle | each circle | R1c (%) |
| C1 | 5 | 1 | 4 | 25 |
| C2 | 15 | 4 | 8 | 50 |
| C3 | 25 | 7 | 14 | 50 |
| C4 | 36 | 17 | 22 | 77 |
| C5 | 46 | 20 | 28 | 71 |
| C6 | 56 | 29 | 36 | 80 |
| C7 | 66 | 38 | 44 | 86 |
| C8 | 76 | 51 | 54 | 94 |
| C9 | 86 | 56 | 58 | 96 |
| C10 | 97 | 61 | 64 | 95 |
| C11 | 107 | 66 | 70 | 94 |
| C12 | 117 | 72 | 74 | 97 |
| C13 | 127 | 58 | 76 | 76 |
| C14 | 137 | 54 | 72 | 75 |
| | | 534 | 624 | 76.4 |
| | | (mark sum) | (symbol sum) | (total mark-ratio) |

In an embodiment, the mark analysis device 220 is further configured to obtain the number of the marks M11 in each circle C1 in the wafer image M1 in FIG. 2B; obtain the number of the supporting post symbols 31 in each circle in the engineer drawing 30 in FIG. 2C; obtain a circle mark-ratio R1c (shown in Table 2 below) of the number of the marks M11 to the number of the supporting post symbols 31 in each circle; and obtain an average of all circle mark-ratios R1c, wherein the average is the total mark-ratio R1t.

In an embodiment, the mark analysis device 220 is further configured to determine whether the total mark-ratio R1t is equal to or less than an allowable value; and when the total mark-ratio R1t is equal to or less than the allowable value, output a warming signal S1 for reminding a user to maintain the electrostatic chuck apparatus 100. The allowable value may be, for example, less than 100%, such as 90%, 85%, 80%, 75%, 70%, 65%, 60%, even lower or higher. The allowable value R1′ may be preset in the mark analysis device 220, for example.

Referring to FIG. 3, FIG. 3 illustrates a schematic diagram of a relationship between the time and the total mark-ratio R1t according to an embodiment of the present disclosure. In an embodiment, the relationship may be stored in the mark analysis device 220.

As illustrated in FIG. 3, the monitoring system 10 may monitor the healthy level of the electrostatic chuck in real time, and the total mark-ratio R1t may be recorded with time. As a result, when the total mark-ratio R1t reaches the allowable value R1′ at time t1′, the mark analysis device 220 may immediately output the warming signal S1 for reminding the user to maintain the electrostatic chuck apparatus 100 in real time.

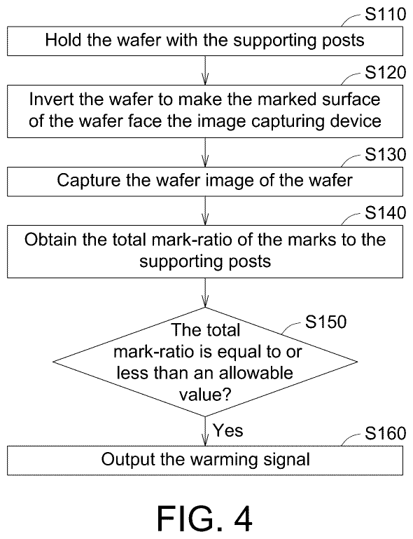

Referring to FIG. 4, FIG. 4 illustrates a schematic diagram of a flow chart of a monitoring method of the monitoring system 10 in FIG. 1A.

In step S110, as illustrated in FIG. 1B, the electrostatic chuck 120 of the electrostatic chuck apparatus 100 may hold the wafer 20 with a plurality of the supporting posts 121 of the electrostatic chuck 120. The wafer 20 is, for example, the blank wafer without any circuit structure, deposition semiconductor film, etc. The marked surface 20s of the wafer 20 faces the electrostatic chuck 120.

In an embodiment, not all supporting posts 121 are in contact with the wafer 20. For example, at least one supporting post 121′ is shorten due to wear and thus can't be in contact with the wafer 20. In this situation, the particles P1 on the terminal surface 121e′ of the supporting post 121′ can't adhere to the wafer 20, and thus the mark M11 can't be formed on the wafer 20. In an embodiment, the brand new (or unused) supporting post has the original height ranging between, for example, 8 micrometers and 12 micrometers. The height h1′ of the supporting post 121 is shorten with usage time of the electrostatic chuck 120, and thus the height h1′ of the supporting post 121′ can't be in contact with the wafer 20. In addition, before the wafer 20 is placed on the electrostatic chuck 120, a plurality of the particles P1 may be formed on the terminal surface 121e of the electrostatic chuck 120 by deposition, for example, plasma. After the plasma, the particles P1 may formed on the plate 122 and all supporting posts 121.

In step S120, as illustrated in FIG. 1C, after chucking operation (as shown in Table 1 above), the wafer 20 may be moved to a position corresponding to the image capturing device 210 of the image detection apparatus 200, and inverted to make the marked surface 20s of the wafer 20 face the image capturing device 210.

In step S130, as illustrated in FIG. 1C, the image capturing device 210 captures the wafer image M1 of the wafer 20. As illustrated in FIG. 2A, the wafer image M1 includes a plurality of the marks M11 corresponding to at least one supporting post symbol 31 in the engineer drawing 30 in FIG. 2C. As illustrated in FIG. 2A, the wafer image M1 may further include at least one marks M11′ not corresponding to at least one of the supporting post symbol 31 in the engineer drawing 30 in FIG. 2C.

In step S140, the mark analysis device 220 may obtain the total mark-ratio Rt of the marks M11 to the supporting post symbol 31 in the engineer drawing 30 in FIG. 2C.

As illustrated in FIG. 2A, not all marks in the wafer image M1 is formed by the supporting post 121. For example, the formation of the mark M11′ is not created by the supporting post 121 while the formation of the mark M11 is created by the supporting post 121. The marks M11 which are formed by the supporting posts 121 are arranged in a plurality of circles C1, each circle C1 has different inner diameter. At least one mark M11′ which are not formed by the supporting posts 121 may be formed on (overlaps) at least one the circles C1 or formed between two circles C1 (not overlap) in the wafer image M1.

The mark analysis device 220 may delete all marks M11′ in the wafer image M1, as illustrated in FIG. 2B. For example, the mark analysis device 220 determines whether each mark in FIG. 2A is corresponding to (in position) any one of all supporting post symbols 31 in the engineer drawing 30 in FIG. 2C; and if there is no supporting post symbol 31 corresponding to each mark in FIG. 2A, delete the mark of the wafer image M11 which is not corresponding to any supporting post symbol 31 in the engineer drawing 30 in FIG. 2C. For example, the mark M11′ appearing in the wafer image M1 of FIG. 2A is not corresponding to any supporting post 121 in the engineer drawing 30, and accordingly the mark analysis device 220 deletes the mark M11′ in the wafer image M1, as illustrated in FIG. 2B.

As illustrated in FIG. 2B, according to the aforementioned deletion method, all marks M11′ which are not created by the supporting post 121 in the wafer image M1 may be deleted.

As shown in Table 2 above, the mark analysis device 220 may obtain the number of the marks M11 of the wafer image M1 in FIG. 2B by, an Image analysis technology. The marks M11 are arranged in a plurality of the circles C1, each circle C1 has different inner diameter. In an embodiment, the mark analysis device 220 may obtain the number of the marks M11 in each circle C1. For example, in the circle C1, the number of the marks M11 is one; in the circle C2, the number of the marks M11 is four.

As shown in Table 2 above, the mark analysis device 220 may obtain the number of the supporting post symbols 31 in each circle C1 according to the engineer drawing 30 in FIG. 2C. For example, in the circle C1, the number of the supporting post symbols 31 is four; in the circle C2, the number of the supporting post symbols 31 is eight.

In an embodiment, as shown in Table 2 above, the mark analysis device 220 may obtain the circle mark-ratio R1c of the number of the marks M11 to the number of the supporting post symbols 31 in each circle C1. For example, in the circle C1, the circle mark-ratio R1c is 25%; in the circle C2, the circle mark-ratio R1c is 50%. After obtaining all circle mark-ratio R1c of all circles C1 (the circle C1 to C14), the mark analysis device 220 may obtain the average of the circle mark-ratios R1c, wherein the average is the total mark-ratio R1t (for example, 76.4% in Table 2 above).

In another embodiment, as shown in Table 2 above, the mark analysis device 220 may obtain the number of all marks M11 of the wafer image M1 in FIG. 2B (for example, 534 in Table 2 above) and obtain the number of all supporting post symbols 31 of the engineer drawing 30 in FIG. 2C (for example, 624 in Table 2 above). After obtaining the number of all marks M11 and the number of all supporting post symbols 31, the mark analysis device 220 may obtain the total mark-ratio R1t of the number of the marks M11 to the number of the supporting post symbols 31 (for example, 76.4%).

In step S150, as illustrated in FIG. 3, the mark analysis device 220 determines whether the total mark-ratio R1t is equal to or less than the allowable value R1′. If the total mark-ratio R1t is greater than the allowable value R1′, the mark analysis device 220 may record the total mark-ratio R1t and update the relationship between the time and the total mark-ratio R1t. If the total mark-ratio R1t is equal to or less than the allowable value R1′, the process proceeds to the step S160.

In S160, the mark analysis device 220 outputs the warming signal S1 for reminding the user to maintain the electrostatic chuck apparatus 100.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a monitoring system, a mark detection apparatus and a monitoring method for healthy of an electrostatic chuck (ESC). The mark detection apparatus may capture a wafer image of a wafer, and obtain a total mark-ratio of the number of the marks in the wafer image to the number of the supporting posts of an electrostatic chuck. The monitoring system may monitor the ESC healthy according to the total mark-ratio.

Example embodiment 1: a monitoring system includes an electrostatic chuck apparatus and a mark detection apparatus. The electrostatic chuck apparatus includes a base and an electrostatic chuck. The electrostatic chuck is disposed on the base, includes a plurality of supporting posts, and is configured to hold a wafer with the supporting posts. The mark detection apparatus includes an image capturing device and a mark analysis device. The image capturing device is configured to capture a wafer image of the wafer, wherein the wafer image includes a plurality of marks corresponding to at least one of the supporting posts. The mark analysis device is electrically connected with the image capturing device and configured to obtain a total mark-ratio of the number of the marks to the number of the supporting posts.

Example embodiment 2 based on Example embodiment 1: the mark analysis device is further configured to obtain the number of the marks; obtain the number of the supporting posts; and obtain the total mark-ratio of the number of the marks to the number of the supporting posts.

Example embodiment 3 based on Example embodiment 1: the marks are arranged in a plurality of circles, each circle has different inner diameter; the mark analysis device is further configured to obtain the number of the marks in each circle; obtain a mark sum of the number of the marks for all circles; and obtain the total mark-ratio of the mark sum to the number of the supporting posts.

Example embodiment 4 based on Example embodiment 1: the marks are arranged in a plurality of circles, each circle has different inner diameter; the mark analysis device is further configured to obtain the number of the marks in each circle; obtain a mark sum of the number of the marks for all circles; obtain the number of the supporting posts according to an engineer drawing; and obtain the total mark-ratio of the mark sum to the number of the supporting posts.

Example embodiment 5 based on Example embodiment 1: the marks are arranged in a plurality of circles, each circle has different inner diameter; the mark analysis device is further configured to obtain the number of the marks in each circle; obtain the number of the supporting posts in each circle according to an engineer drawing; obtain a circle mark-ratio of the number of the marks to the number of the supporting posts for each circle; and obtain an average of the circle mark-ratios, wherein the average is the total mark-ratio.

Example embodiment 6 based on Example embodiment 1: the mark analysis device is further configured to determine whether the total mark-ratio is equal to or less than an allowable value; and when the total mark-ratio is equal to or less than the allowable value, output a warming signal.

Example embodiment 7 based on Example embodiment 1: the mark analysis device is further configured to determine whether a compared one of the marks is corresponding to any one of the supporting posts in position; and if there is no supporting post corresponding to the compared one, delete the compared one in the wafer image.

Example embodiment 8: a mark detection apparatus includes an image capturing device and a mark analysis device. The image capturing device is configured to capture a wafer image of a wafer, wherein the wafer image includes a plurality of marks, and at least one of the marks is corresponding to at least one of supporting posts of an electrostatic chuck. The analysis device is electrically connected with the image capturing device and configured to obtain a total mark-ratio of the number of the marks to the number of the supporting posts.

Example embodiment 9 based on Example embodiment 8: the analysis device is further configured to obtain the number of the marks; obtain the number of the supporting posts; and obtain the total mark-ratio of the number of the marks to the number of the supporting posts.

Example embodiment 10 based on Example embodiment 8: the marks are arranged in a plurality of circles, each circle has different inner diameter; the mark analysis device is further configured to obtain the number of the marks in each circle; obtain a mark sum of the number of the marks for all circles; and obtain the total mark-ratio of the mark sum to the number of the supporting posts.

Example embodiment 11 based on Example embodiment 8: the marks are arranged in a plurality of circles, each circle has different inner diameter; the mark analysis device is further configured to obtain the number of the marks in each circle; obtain a mark sum of the number of the marks for all circles; obtain the number of the supporting posts according to an engineer drawing; and obtain the total mark-ratio of the mark sum to the number of the supporting posts.

Example embodiment 12 based on Example embodiment 8: the marks are arranged in a plurality of circles, each circle has different inner diameter; the analysis device is further configured to obtain the number of the marks in each circle; obtain the number of the supporting posts in each circle according to an engineer drawing; obtain a circle mark-ratio of the number of the marks to the number of the supporting posts for each circle; and obtain an average of the circle mark-ratios, wherein the average is the total mark-ratio.

Example embodiment 13 based on Example embodiment 8: the mark analysis device is further configured to determine whether the total mark-ratio is equal to or less than an allowable value; and when the total mark-ratio is equal to or less than the allowable value, output a warming signal.

Example embodiment 14 based on Example embodiment 8: the mark analysis device is further configured to determine whether a compared one of the marks is corresponding to any one of the supporting posts in position; and if there is no supporting post corresponding to the compared one, delete the compared one in the wafer image.

Example embodiment 15: a monitoring method for ESC healthy includes the following steps: holding, by an electrostatic chuck of an electrostatic chuck apparatus, a wafer with a plurality of supporting posts of the electrostatic chuck; capturing, by an image capturing device, a wafer image of the wafer, wherein the wafer image includes a plurality of marks, and at least one of the marks is corresponding to at least one of the supporting posts; and obtaining, by a mark analysis device, a total mark-ratio of the number of the marks to the number of the supporting posts.

Example embodiment 16 based on Example embodiment 15: the monitoring method further includes: forming a plurality of particles on a terminal surface of each supporting post.

Example embodiment 17 based on Example embodiment 15: the monitoring method further includes: obtaining, by the mark analysis device, the number of the marks; obtaining, by the mark analysis device, the number of the supporting posts; and obtaining, by the mark analysis device, the total mark-ratio of the number of the marks to the number of the supporting posts.

Example embodiment 18 based on Example embodiment 15: the marks are arranged in a plurality of circles, each circle has different inner diameter; the monitoring method further includes: obtaining, by the mark analysis device, the number of the marks in each circle; obtaining, by the mark analysis device, a mark sum of the number of the marks for all circles; and obtaining, by the mark analysis device, the total mark-ratio of the mark sum to the number of the supporting posts.

Example embodiment 19 based on Example embodiment 15: the marks are arranged in a plurality of circles, each circle has different inner diameter; the monitoring method further includes: obtaining, by the mark analysis device, the number of the marks in each circle; obtaining, by the mark analysis device, a mark sum of the number of the marks for all circles; obtaining, by the mark analysis device, the number of the supporting posts according to an engineer drawing; and obtaining, by the mark analysis device, the total mark-ratio of the mark sum to the number of the supporting posts.

Example embodiment 20 based on Example embodiment 15: the marks are arranged in a plurality of circles, each circle has different inner diameter; the monitoring method further includes obtaining, by the mark analysis device, the number of the marks in each circle; obtaining, by the mark analysis device, the number of the supporting posts in each circle according to an engineer drawing; obtaining, by the mark analysis device, a circle mark-ratio of the number of the marks to the number of the supporting posts for each circle; and obtaining, by the mark analysis device, an average of the circle mark-ratios, wherein the average is the total mark-ratio.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A monitoring system, comprising:
an electrostatic chuck apparatus, comprising:
a base; and
an electrostatic chuck (ESC) disposed on the base, comprising a plurality of supporting posts, and configured to:
hold a wafer with the supporting posts; and
a mark detection apparatus, comprising:
an image capturing device, configured to:
capture a wafer image of the wafer, wherein the wafer image comprises a plurality of marks, and at least one of the marks is corresponding to at least one of the supporting posts; and
a mark analysis device electrically connected with the image capturing device and configured to:
obtain a total mark-ratio of the number of the marks to the number of the supporting posts.

2. The monitoring system according to claim 1, wherein the mark analysis device is further configured to:
obtain the number of the marks;
obtain the number of the supporting posts; and
obtain the total mark-ratio of the number of the marks to the number of the supporting posts.

3. The monitoring system according to claim 1, wherein the marks are arranged in a plurality of circles, each circle has different inner diameter; the mark analysis device is further configured to:
obtain the number of the marks in each circle;
obtain a mark sum of the number of the marks for all circles; and
obtain the total mark-ratio of the mark sum to the number of the supporting posts.

4. The monitoring system according to claim 1, wherein the marks are arranged in a plurality of circles, each circle has different inner diameter; the mark analysis device is further configured to:
obtain the number of the marks in each circle;
obtain a mark sum of the number of the marks for all circles;
obtain the number of the supporting posts according to an engineer drawing; and
obtain the total mark-ratio of the mark sum to the number of the supporting posts.

5. The monitoring system according to claim 1, wherein the marks are arranged in a plurality of circles, each circle has different inner diameter; the mark analysis device is further configured to:
obtain the number of the marks in each circle;
obtain the number of the supporting posts in each circle according to an engineer drawing;
obtain a circle mark-ratio of the number of the marks to the number of the supporting posts for each circle; and
obtain an average of the circle mark-ratios, wherein the average is the total mark-ratio.

6. The monitoring system according to claim 1, wherein the mark analysis device is further configured to:
determine whether the total mark-ratio is equal to or less than an allowable value; and
when the total mark-ratio is equal to or less than the allowable value, output a warming signal.

7. The monitoring system according to claim 1, wherein the mark analysis device is further configured to:
determine whether a compared one of the marks is corresponding to any one of the supporting posts in position; and
if there is no supporting post corresponding to the compared one, delete the compared one in the wafer image.

8. A mark detection apparatus, comprising:
an image capturing device, configured to:
capture a wafer image of a wafer, wherein the wafer image comprises a plurality of marks, and at least one of the marks is corresponding to at least one of supporting posts of an electrostatic chuck of an electrostatic chuck apparatus; and
an analysis device electrically connected with the image capturing device and configured to:
obtain a total mark-ratio of the number of the marks to the number of the supporting posts.

9. The mark detection apparatus according to claim 8, wherein the analysis device is further configured to:
obtain the number of the marks;
obtain the number of the supporting posts; and
obtain the total mark-ratio of the number of the marks to the number of the supporting posts.

10. The mark detection apparatus according to claim 8, wherein the marks are arranged in a plurality of circles, each circle has different inner diameter; the mark analysis device is further configured to:
obtain the number of the marks in each circle;
obtain a mark sum of the number of the marks for all circles; and
obtain the total mark-ratio of the mark sum to the number of the supporting posts.

11. The mark detection apparatus s according to claim 8, wherein the marks are arranged in a plurality of circles, each circle has different inner diameter; the mark analysis device is further configured to:
obtain the number of the marks in each circle;
obtain a mark sum of the number of the marks for all circles;
obtain the number of the supporting posts according to an engineer drawing; and
obtain the total mark-ratio of the mark sum to the number of the supporting posts.

12. The mark detection apparatus according to claim 8, wherein the marks are arranged in a plurality of circles, each circle has different inner diameter; the analysis device is further configured to:
obtain the number of the marks in each circle;
obtain the number of the supporting posts in each circle according to an engineer drawing;
obtain a circle mark-ratio of the number of the marks to the number of the supporting posts for each circle; and
obtain an average of the circle mark-ratios, wherein the average is the total mark-ratio.

13. The mark detection apparatus according to claim 8, wherein the mark analysis device is further configured to:
determine whether the total mark-ratio is equal to or less than an allowable value; and
when the total mark-ratio is equal to or less than the allowable value, output a warming signal.

14. The mark detection apparatus according to claim 8, wherein the mark analysis device is further configured to:
determine whether a compared one of the marks is corresponding to any one of the supporting posts in position; and
if there is no supporting post corresponding to the compared one, delete the compared one in the wafer image.

15. A monitoring method for ESC healthy, comprising:
holding, by an electrostatic chuck of an electrostatic chuck apparatus, a wafer with a plurality of supporting posts of the electrostatic chuck;
capturing, by an image capturing device, a wafer image of the wafer, wherein the wafer image comprises a plurality of marks, and at least one of the marks is corresponding to at least one of the supporting posts; and
obtaining, by a mark analysis device, a total mark-ratio of the number of the marks to the number of the supporting posts.

16. The monitoring method according to claim 15, further comprising:
forming a plurality of particles on a terminal surface of each supporting post.

17. The monitoring method according to claim 15, further comprising:
obtaining, by the mark analysis device, the number of the marks;
obtaining, by the mark analysis device, the number of the supporting posts; and
obtaining, by the mark analysis device, the total mark-ratio of the number of the marks to the number of the supporting posts.

18. The monitoring method according to claim 15, wherein the marks are arranged in a plurality of circles, each circle has different inner diameter; the monitoring method further comprising:
obtaining, by the mark analysis device, the number of the marks in each circle;
obtaining, by the mark analysis device, a mark sum of the number of the marks for all circles; and
obtaining, by the mark analysis device, the total mark-ratio of the mark sum to the number of the supporting posts.

19. The monitoring method according to claim 15, wherein the marks are arranged in a plurality of circles, each circle has different inner diameter; the monitoring method further comprising:
obtaining, by the mark analysis device, the number of the marks in each circle;
obtaining, by the mark analysis device, a mark sum of the number of the marks for all circles;
obtaining, by the mark analysis device, the number of the supporting posts according to an engineer drawing; and
obtaining, by the mark analysis device, the total mark-ratio of the mark sum to the number of the supporting posts.

20. The monitoring method according to claim 15, wherein the marks are arranged in a plurality of circles, each circle has different inner diameter; the monitoring method further comprising:
obtaining, by the mark analysis device, the number of the marks in each circle;
obtaining, by the mark analysis device, the number of the supporting posts in each circle according to an engineer drawing;
obtaining, by the mark analysis device, a circle mark-ratio of the number of the marks to the number of the supporting posts for each circle; and
obtaining, by the mark analysis device, an average of the circle mark-ratios, wherein the average is the total mark-ratio.
